(19) United States
(12) Patent Application Publication
(10) Pub. No.: US 2025/0378231 A1
(43) Pub. Date: Dec. 11, 2025

(54) WEIGHTED THERMAL SENSOR CLUSTERING SYSTEM AND METHOD

(71) Applicant: Dell Products L.P., Round Rock, TX (US)

(72) Inventors: Tao-Peng Chu, Taipei (TW); Shao-Hung Yu, New Taipei City (TW); Ting-Chiang Huang, New Taipei City (TW); Chen Hsin Chang, Keelung (TW); Wei-Che Hsiao, New Taipei City (TW)

(73) Assignee: Dell Products L.P., Round Rock, TX (US)

(21) Appl. No.: 18/735,318

(22) Filed: Jun. 6, 2024

(51) Int. Cl. G06F 30/27

(52) U.S. Cl. CPC G06F 30/27

(57) ABSTRACT

Systems and methods integrating machine learning to optimize the placement of heat sources and thermal sensors through new design clustering methods and to identify potential problems at the early stages of design are described. In an illustrative, non-limiting embodiment, an Information Handling System (IHS) includes instructions to receive a component location file that indicates the location of a plurality of components on a printed circuit board (PCB), identify an optimal location of a plurality of heat source clusters on a computing device using the component location file, and display the heat source clusters along with their location relative to the computing device on a user interface for view by the user.

### BACKGROUND

As the value and use of information continues to increase, individuals and businesses seek additional ways to process and store it. One option available to users is an Information Handling System (IHS). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated.

Variations in IHSs allow for IHSs to be general or configured for a specific user or specific use, such as financial transaction processing, airline reservations, enterprise data storage, or global communications. In addition, IHSs may include a variety of hardware and software components that may be configured to process, store, and communicate information and may include one or more computer systems, data storage systems, and networking systems.

In recent years, as IHS components such as processors, graphics cards, random access memory (RAM), etc. have increased in clock speed and power consumption, the amount of heat produced by such components during normal operation has also increased. Often, the temperatures of these components need to be kept within a selected range to prevent overheating, instability, malfunction, and damage leading to a shortened component lifespan. Accordingly, cooling systems are often implemented in IHSs to cool certain heat generating components.

### SUMMARY

Systems and methods integrating machine learning to optimize the placement of heat sources and thermal sensors through new design clustering methods and to identify potential problems at the early stages of design are described. In an illustrative, non-limiting embodiment, an Information Handling System (IHS) includes instructions to receive a component location file that indicates the location of a plurality of components on a printed circuit board (PCB), identify an optimal location of a plurality of heat source clusters on a computing device using the component location file, and display the heat source clusters along with their location relative to the computing device on a user interface for view by the user.

According to another embodiment, a weighted thermal sensor clustering method includes the steps of receiving a component location file that indicates the location of a plurality of components on a printed circuit board (PCB), identifying an optimal location of a plurality of heat source clusters on a computing device using the component location file, and displaying the heat source clusters along with their location relative to the computing device on a user interface for view by the user.

According to yet another embodiment, a non-transitory memory storage device has program instructions stored thereon that, upon execution by one or more processors of a client Information Handling System (IHS), cause the IHS to receive a component location file that indicates the location of a plurality of components on a printed circuit board (PCB), identify an optimal location of a plurality of heat source clusters on a computing device using the component location file, and display the heat source clusters along with their location relative to the computing device on a user interface for view by the user.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIG. 1 is a diagram illustrating examples of components of an Information Handling System (IHS) that may be used to implement a weighted thermal sensor clustering system according to one embodiment of the present disclosure.

FIG. 2 illustrates an example weighted thermal sensor clustering system that may be used to map clusters of heat sources on a computing device, and display the clusters for view by a user according to one embodiment of the present disclosure.

FIG. 3 illustrates one embodiment of a weighted thermal sensor clustering method that may be performed to identify an optimal placement of clusters representing a collection or grouping of heat generating components according to one embodiment of the present disclosure.

FIG. 4 illustrates another embodiment of a weighted thermal sensor clustering method that may be performed to identify an optimal quantity and placement of clusters representing a collection of heat generating components according to one embodiment of the present disclosure.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

For purposes of this disclosure, an Information Handling System (IHS) may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a network storage device, or any other suitable device and may vary in size, shape, performance, functionality, and price.

An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

An IHS embodied as a server is typically configured with multiple computing devices, such as NIC cards, I/O cards, video cards, and the like. Many of these computing devices are often provided as printed circuit boards (PCBs) on which multiple electronic components (e.g., IC chips, transistors, capacitors, resistors, etc.) are mounted. Nevertheless, some of the components may generate varying levels of heat during their operation. As such, thermal sensors may be mounted on the PCBs to continually monitor the temperature to ensure that no over-heating occurs.

The placement of thermal sensors and heat sources on a PCB is often crucial to the overall thermal design of computing devices. Many lessons have been learned about the arrangement of heat sources (e.g., heat generating components) and thermal sensors in the past. For example, unanticipated heat sources have disrupted thermal sensors, leading them to report inaccurate temperatures, which has resulted in system throttling or even unexpected system power shutdowns, among other issues. Conventionally, during design of the computing device, the positioning of sensors is manually determined based on the designer's expertise. When the computing device is validated following design, system-level testing and engineering tests are conducted based on certain defined test scenarios. This regimen, however, might be insufficient for managing certain hidden risks associated with system issues that remain undetected by current test scenarios.

In a conventional design approach, during Engineering Validation Test (EVT) stage, PCB design engineers mainly conduct thermal sensor placement based on the location of the heat sources and the temperature of the parts to be measured. This typically involves simulation, and during the MOCK-UP stage, initial adjustments and validations are carried out. In the subsequent validation stage, engineers validate the system based on the thermal specifications, and the validation team performs extensive validation of the entire system based on test cases. Traditionally, a lot of time is often needed to qualify the system in order to catch (e.g., identify) corner cases. However, based on lessons learned in recent years, unexpected heat sources that only generate heat under specific circumstances often become the main cause of late-found issues.

Recognizing this, the inventors have conducted extensive analysis and research on the issue and as a result, have developed a weighted thermal sensor clustering system that facilitates advanced analysis of a computing device's heat sources and thermal sensors. As will be described in detail herein below, the weighted thermal sensor clustering system integrates machine learning to optimize the placement of heat sources and thermal sensors through new design clustering methods and to identify potential problems at the early stages of design.

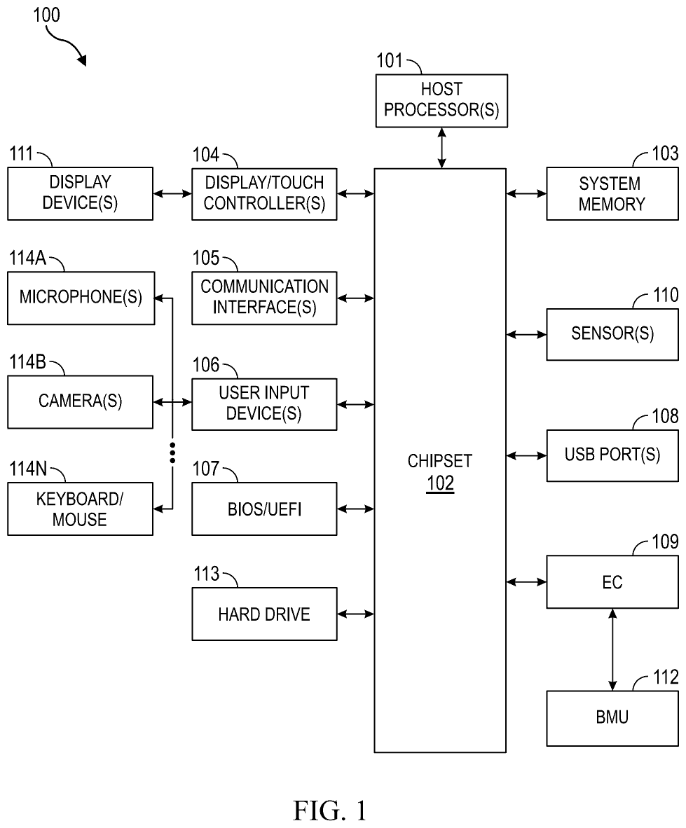

FIG. 1 is a block diagram of components of IHS 100 that may be used to implement a weighted thermal sensor clustering system according to one embodiment of the present disclosure. As depicted, IHS 100 includes host processor(s) 101. In various embodiments, IHS 100 may be a single-processor system, or a multi-processor system including two or more processors. Host processor(s) 101 may include any processor capable of executing program instructions, such as an INTEL/AMD x86 processor, or any general-purpose or embedded processor implementing any of a variety of Instruction Set Architectures (ISAs), such as a Complex Instruction Set Computer (CISC) ISA, a Reduced Instruction Set Computer (RISC) ISA (e.g., one or more ARM core(s), or the like).

IHS 100 includes chipset 102 coupled to host processor(s) 101. Chipset 102 may provide host processor(s) 101 with access to several resources. In some cases, chipset 102 may utilize a QuickPath Interconnect (QPI) bus to communicate with host processor(s) 101. Chipset 102 may also be coupled to communication interface(s) 105 to enable communications between IHS 100 and various wired and/or wireless networks, such as Ethernet, WiFi, BT, cellular or mobile networks (e.g., Code-Division Multiple Access or “CDMA,” Time-Division Multiple Access or “TDMA,” Long-Term Evolution or “LTE,” etc.), satellite networks, or the like.

Communication interface(s) 105 may be used to communicate with peripheral devices (e.g., BT speakers, microphones, headsets, etc.). Moreover, communication interface(s) 105 may be coupled to chipset 102 via a Peripheral Component Interconnect Express (PCIe) bus, or the like.

Chipset 102 may be coupled to display and/or touchscreen controller(s) 104, which may include one or more Graphics Processor Units (GPUs) on a graphics bus, such as an Accelerated Graphics Port (AGP) or PCIe bus. As shown, display controller(s) 104 provide video or display signals to one or more display device(s) 111.

Display device(s) 111 may include Liquid Crystal Display (LCD), Light Emitting Diode (LED), organic LED (OLED), or other thin film display technologies. Display device(s) 111 may include a plurality of pixels arranged in a matrix, configured to display visual information, such as text, two-dimensional images, video, three-dimensional images, etc. In some cases, display device(s) 111 may be provided as a single continuous display, rather than two discrete displays.

Chipset 102 may provide host processor(s) 101 and/or display controller(s) 104 with access to system memory 103. In various embodiments, system memory 103 may be implemented using any suitable memory technology, such as static RAM (SRAM), dynamic RAM (DRAM) or magnetic disks, or any nonvolatile/Flash-type memory, such as a Solid-State Drive (SSD), Non-Volatile Memory Express (NVMe), or the like.

In certain embodiments, chipset 102 may also provide host processor(s) 101 with access to one or more Universal Serial Bus (USB) ports/controllers 108, to which one or more peripheral devices may be coupled (e.g., integrated or external webcams, microphones, speakers, etc.).

Chipset 102 may further provide host processor(s) 101 with access to one or more hard disk drives, solid-state drives, optical drives, or other removable-media drives 113.

Chipset 102 may also provide access to one or more user input devices 106, for example, using a super I/O controller or the like. Examples of user input devices 106 include, but are not limited to, microphone(s) 114A, camera(s) 114B, and keyboard/mouse 114N. Other user input devices 106 may include a touchpad, stylus or active pen, totem, etc. Each user input device 106 may include a respective controller (e.g., a touchpad may have its own touchpad controller) that interfaces with chipset 102 through a wired or wireless connection (e.g., via communication interfaces(s) 105).

In some cases, chipset 102 may also provide access to one or more user output devices (e.g., video projectors, paper printers, 3D printers, loudspeakers, audio headsets, Virtual/Augmented Reality (VR/AR) devices, etc.).

In certain embodiments, chipset 102 may further provide an interface for communications with one or more hardware sensors 110. Sensors 110 may be disposed on or within the chassis of IHS 100, or otherwise coupled to IHS 100, and may include, but are not limited to: electric, magnetic, radio, optical (e.g., camera, webcam, etc.), infrared, thermal, force, pressure, acoustic (e.g., microphone), ultrasonic, proximity, position, deformation, bending, direction, movement, velocity, rotation, gyroscope, Inertial Measurement Unit (IMU), and/or acceleration sensor(s).

BIOS/UEFI 107 is coupled to chipset 102. UEFI was designed as a successor to BIOS, and many modern IHSs utilize UEFI in addition to or instead of a BIOS. Accordingly, BIOS/UEFI 107 is intended to also encompass a UEFI component. BIOS/UEFI 107 provides an abstraction layer that allows the OS to interface with certain hardware components that are utilized by IHS 100.

Upon booting of IHS 100, host processor(s) 101 may utilize program instructions of BIOS 107 to initialize and test hardware components coupled to IHS 100, and to load a host OS for use by IHS 100. Via the hardware abstraction layer provided by BIOS/UEFI 107, software stored in system memory 103 and executed by host processor(s) 101 can interface with I/O devices coupled to IHS 100.

Embedded Controller (EC) 109 (sometimes referred to as a Baseboard Management Controller or “BMC”) includes a microcontroller unit or processing core dedicated to handling selected IHS operations not ordinarily handled by host processor(s) 101. Additionally, one or more thermal sensors 120 may be coupled to EC 109.

Examples of such operations may include, but are not limited to: power sequencing, power management, receiving and processing signals from a keyboard or touchpad, as well as other buttons and switches (e.g., power button, laptop lid switch, etc.), receiving and processing thermal measurements (e.g., performing cooling fan control, throttling CPUs and GPUs, controlling cooling fan speeds, and emergency shutdown), controlling indicator Light-Emitting Diodes or “LEDs” (e.g., caps lock, scroll lock, num lock, battery, ac, power, wireless LAN, sleep, etc.), managing the battery charger and the battery, enabling remote or Out-of-Band (OOB) management, diagnostics, and remediation over network(s), and the like.

Unlike other devices in IHS 100, EC 109 may be made operational from the very start of each power reset, before other devices are fully running or powered on. As such, EC 109 may be responsible for interfacing with a power adapter to manage the power consumption of IHS 100. These operations may be utilized to determine the power status of IHS 100, such as whether IHS 100 is operating from battery power or is plugged into an AC power source. Firmware instructions utilized by EC 109 may be used to manage other core operations of IHS 100 (e.g., turbo modes, maximum operating clock frequencies of certain components, etc.).

In some cases, EC 109 may implement operations for detecting certain changes to the physical configuration or posture of IHS 100 and managing other devices in different configurations of IHS 100. For instance, when IHS 100 as a 2-in-1 laptop/tablet form factor, EC 109 may receive inputs from a lid position or hinge angle sensor 110, and it may use those inputs to determine: whether the two sides of IHS 100 have been latched together to a closed position or a tablet position, the magnitude of a hinge or lid angle, etc. In response to these changes, the EC may enable or disable certain features of IHS 100 (e.g., front or rear facing camera, etc.).

In some implementations, EC 109 may be installed as a Trusted Execution Environment (TEE) component to the motherboard of IHS 100. Additionally, or alternatively, EC 109 may be further configured to calculate hashes or signatures that uniquely identify individual components of IHS 100. In such scenarios, EC 109 may calculate a hash value based on the configuration of a hardware and/or software component coupled to IHS 100. For instance, EC 109 may calculate a hash value based on all firmware and other code or settings stored in an onboard memory of a hardware component.

Hash values may be calculated as part of a trusted process of manufacturing IHS 100 and may be maintained in secure storage as a reference signature. EC 109 may later recalculate the hash value for a component to compare it against the reference hash value to determine if any modifications have been made to the component, thus indicating that the component has been compromised. As such, EC 109 may validate the integrity of hardware and software components installed in IHS 100.

In addition, EC 109 may provide an Out-of-Band communication channel that allows an Information Technology Decision Maker (ITDM) or Original Equipment Manufacturer (OEM) to manage IHS 100's various settings and configurations, for example, by issuing OOB commands.

In various embodiments, IHS 100 may be coupled to an external power source through an AC adapter, power brick, or the like. The AC adapter may be removably coupled to a battery charge controller to provide IHS 100 with a source of DC power provided by battery cells of a battery system in the form of a battery pack (e.g., a lithium ion or “Li-ion” battery pack, or a nickel metal hydride or “NiMH” battery pack including one or more rechargeable batteries).

Battery Management Unit (BMU) 112 may be coupled to EC 109 and it may include, for example, an Analog Front End (AFE), storage (e.g., non-volatile memory), and a microcontroller. In some cases, BMU 112 may be configured to collect and store information, and to provide that information to other IHS components, such as, for example devices within the IHS 100.

Examples of information collectible by BMU 112 may include, but are not limited to: operating conditions (e.g., battery operating conditions including battery state information such as battery current amplitude and/or current direction, battery voltage, battery charge cycles, battery state of charge, battery state of health, battery temperature, battery usage data such as charging and discharging data; and/or IHS operating conditions such as processor operating speed data, system power management and cooling system settings, state of “system present” pin signal), environmental or contextual information or state (e.g., such as ambient temperature, relative humidity, system geolocation measured by GPS or triangulation, time and date, etc.), events, etc.

Examples of events may include, but are not limited to: acceleration or shock events, system transportation events, exposure to elevated temperature for extended time periods, high discharge current rate, combinations of battery voltage, battery current and/or battery temperature (e.g., elevated temperature event at full charge and/or high voltage causes more battery degradation than lower voltage), etc.

In some embodiments, IHS 100 may not include all the components shown in FIG. 1. In other embodiments, IHS 100 may include other components in addition to those that are shown in FIG. 1. Furthermore, some components that are represented as separate components in FIG. 1 may instead be integrated with other components, such that all or a portion of the operations executed by the illustrated components may instead be executed by the integrated component.

For example, in various embodiments described herein, host processor(s) 101 and/or other components shown in FIG. 1 (e.g., chipset 102, display controller(s) 104, communication interface(s) 105, EC 109, etc.) may be replaced by devices within the IHS 100. As such, IHS 100 may assume different form factors including, but not limited to: servers, workstations, desktops, laptops, appliances, video game consoles, tablets, smartphones, etc.

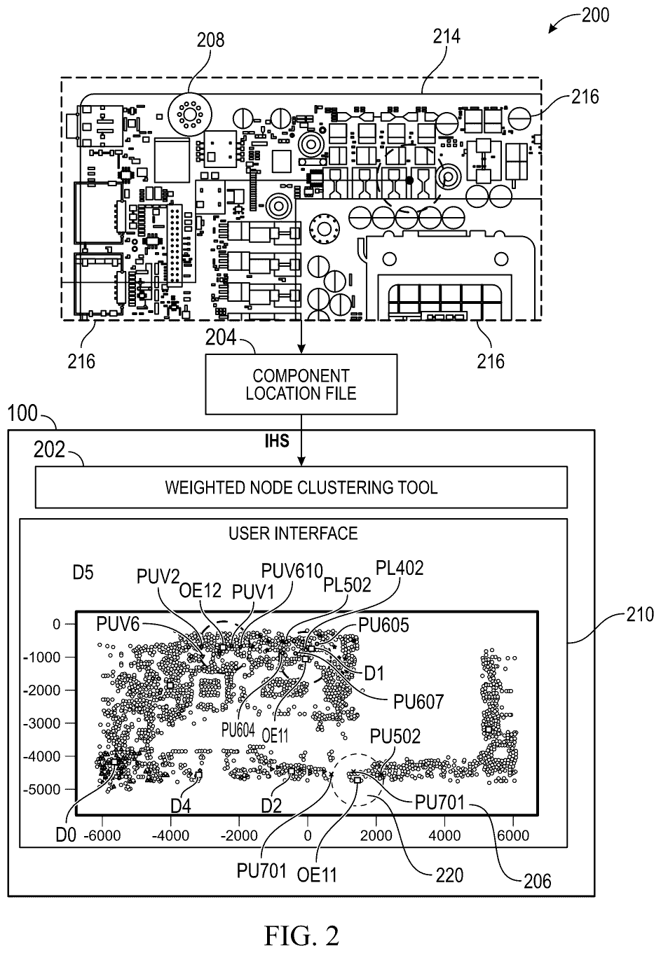

FIG. 2 illustrates an example weighted thermal sensor clustering system 200 that may be used to map clusters of heat sources on a computing device, and display the clusters for view by a user according to one embodiment of the present disclosure. The weighted thermal sensor clustering system 200 includes a weighted thermal sensor clustering tool 202 that is executed on an IHS 100 to receive a component location file 204, identify an optimal number, size, and location of heat source clusters 206 on a computing device 208 using the component location file 204, and display the heat source clusters 206 along with their location relative to the computing device 208 on a user interface 210 for view by the user.

Generally speaking, the weighted thermal sensor clustering system 200 integrates the locations of components and the component location file 204 (e.g., power source on board file) to determine the optimal design for the system's heat sources and thermal sensors, including their locations and quantities, and to provide data visualization capabilities for viewing the locations of the clusters 206. The heat source clusters 206 may be used to indicate an optimal quantity and placement of thermal sensors on the PCB 214. For example, each cluster 206 may be displayed with a centroid 220 representing an optimal location for placement of a thermal sensor.

The computing device 208 generally includes a PCB 214 on which multiple components 216 may be mounted. As mentioned previously, certain components 216 may generate more heat than others. As such, the component location file 204 may include information about the location of each components 216 on the PCB 214 along with its power usage information that can be used to estimate an amount of heat that it will generate. The power usage information may include, for example, a component's normal rated power usage, a maximum rated power usage, and a minimum rate power usage. In one embodiment, the component location file 204 may be provided as an xlsx file.

According to one embodiment, the weighted thermal sensor clustering tool 202 utilizes a Machine Learning (ML) tool to identify the optimal designation of certain heat generating components 216 into one or more clusters 206. In another embodiment, the weighted thermal sensor clustering system 200 uses either a K-means classifier or a revised K-means classifier to perform iterative clustering and integrating power budget weight distribution to optimize output results.

According to another embodiment, the weighted thermal sensor clustering tool 202 performs a Min-Max Normalizing Power Budget weighting factor to each of the components listed in the component location file 204. The Min-Max Normalizing Power Budget weighting factor may be performed using the following formula:

$${x}_{scaled} = \frac{x - {x}_{min}}{{x}_{max} - {x}_{min}}$$

Where: x_{scaled} is a weighting factor to be applied to the component, x is the normal rated power usage of the component, xₘᵢₙ is the minimum rated power usage of the component, and xₘₐₓ is the maximum rated power usage of the component.

The min-max normalizing power budget weighting factor may be useful for identifying those components that are susceptible to over-heating and adjusting a weighting factor (x_{scaled}) so that the weighted thermal sensor clustering tool 202 will move the centroid 220 closer to those components 216. Moreover, the weighted thermal sensor clustering tool 202 uses the min-max normalizing power budget weighting factor to determine a level of sensitivity of required cooling to each of the heat generating components 216 so that the centroid 220 of each cluster 206 may be adjusted to be physically closer to those components 216 having a higher level of sensitivity.

In one embodiment, the weighted thermal sensor clustering tool 202 may provide for dedicated sensor placement. For example, one component 216 may exist that has a cooling sensitivity sufficiently high to warrant a thermal sensor directly onto or in relative close proximity so that its temperature may be monitored independently of any other components 216. Thus, the weighted thermal sensor clustering tool 202 may receive user input for obtaining a location where the dedicated thermal sensor is to be placed. In another embodiment, the weighted thermal sensor clustering tool 202 may provide for manual placement of a sensor location. For example, the weighted thermal sensor clustering tool 202 may be configured to receive user input for a sensor location nearby to one or a group of heat generating components 216.

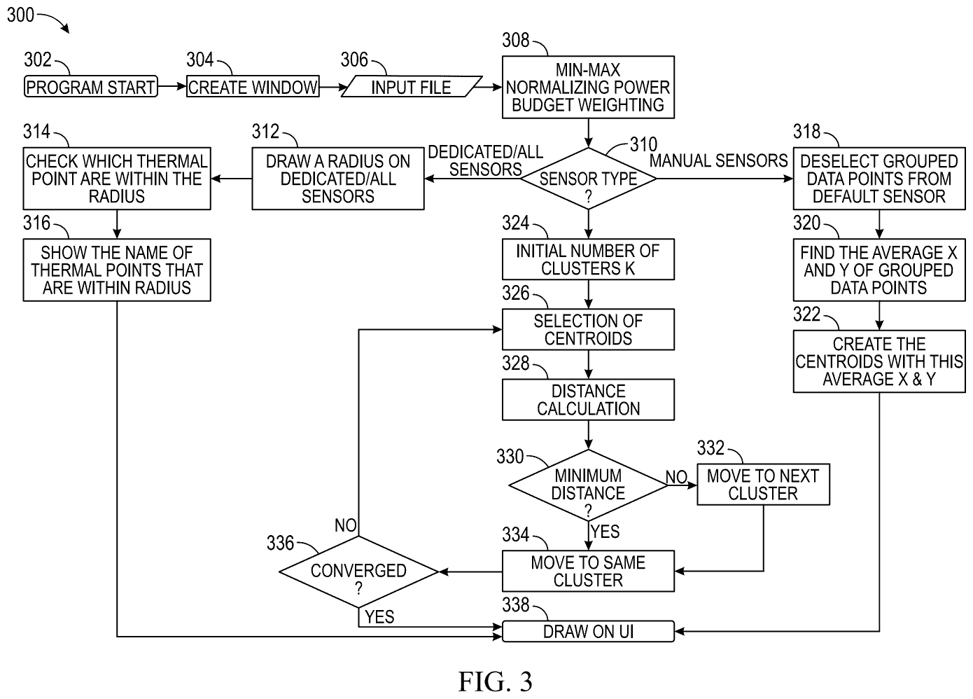

FIG. 3 illustrates one embodiment of a weighted thermal sensor clustering method 300 that may be performed to identify an optimal placement of clusters 206 representing a collection or grouping of heat generating components according to one embodiment of the present disclosure. The weighted thermal sensor clustering method 300 may be performed at any suitable time. For example, the weighted thermal sensor clustering method 300 may be performed during the design phase of a computing device 208, or during system level validation of an IHS 100 where the computing device 208 is to be deployed in.

Initially at step 302, the weighted thermal sensor clustering tool 202 is started. Once started, the weighted thermal sensor clustering tool 202 generates a window on the user interface 210 at step 304. At step 306, the weighted thermal sensor clustering tool 202 receives a component location file 204. Thereafter at step 308, the weighted thermal sensor clustering tool 202 obtains a Min-Max Normalizing Power Budget weighting for each of the components 216 on the PCB 214.

At step 310, the weighted thermal sensor clustering tool 202 receives user input for identifying any dedicated sensors or manually placed sensors. If the weighted thermal sensor clustering tool 202 receives user input for dedicated placement of a sensor, processing continues at step 312 in which it draws a radius around the dedicated sensor placement, checks for any other components 216 that may exist within that radius at step 314, and displays those other components 216 that may be within that radius at step 316. Thereafter, the weighted thermal sensor clustering tool 202 draws the dedicated cluster 206 along with the dedicated component 216 and any other components 216 within the radius on the user interface 210.

Referring again to step 310, if the weighted thermal sensor clustering tool 202 receives user input for manual placement of a sensor, processing continues at step 318 in which it deselects the grouped data points a default sensor placement. That is, the weighted thermal sensor clustering tool 202 removes any data points from the components 216 for processing because the sensor placement is selected manually. Also the weighted thermal sensor clustering tool 202 finds the average X and Y placement of the grouped data points at step 320, and creates a centroid 220 including the X and Y placement that it found at step 322.

Referring again to step 310, the weighted thermal sensor clustering tool 202 begins processing all the remaining default sensors (clusters) that are not dedicated or manually selected by initially identifying how many remaining (default) clusters 206 are to be used at step 324.

Steps 326-336 generally describe a process for iteratively selecting a placement of the clusters based upon the location of the heat generating components 216 on the PCB 214. At step 326, the weighted thermal sensor clustering tool 202 identifies an initial placement of the centroids of the clusters 206, and at step 328, calculates a distance of the components 216 from the identified centroid location. In one embodiment, the weighted thermal sensor clustering tool 202 uses a ML learning tool identify a placement of centroids 220. In another embodiment, the weighted thermal sensor clustering tool 202 uses either a K-means classifier or a revised K-means classifier to identify a placement of the centroids 220. In yet another embodiment, the weighted thermal sensor clustering tool 202 may adjust the calculated distance for each component 216 based upon the min-max normalizing power budget weighting factor calculated for that component 216. For example, the weighted thermal sensor clustering tool 202 may move the centroid 220 closer to those components having a relatively high heat budget sensitivity than other components 216 having a lower heat budget sensitivity.

At step 330, the weighted thermal sensor clustering tool 202 determines, for each component 216, whether it is at a minimum distance from a particular centroid 220. If not, that component 216 is moved to another centroid 220 at step 332. If, however, that component 216 is within a specified distance from that centroid 220, the component 216 is designated to belong to that cluster 206 at step 334.

Using the selected groupings for the components 216 in each of the clusters 206, the weighted thermal sensor clustering tool 202 determines whether the placement of the centroids 220 is sufficiently converged at step 336. That is, the weighted thermal sensor clustering tool 202 determines whether the centroids 220 are optimally placed or not. If the centroids 220 are not optimally placed, processing continues at step 326 to again select another placement for the centroids 220 that would reduce the distance of the centroids 220 from the heat generating components 216. If, however, the centroids 220 are considered to be optimally placed, the centroids 220 are displayed on the user interface 210 for view by the user, and at this point, the method 300 has ended.

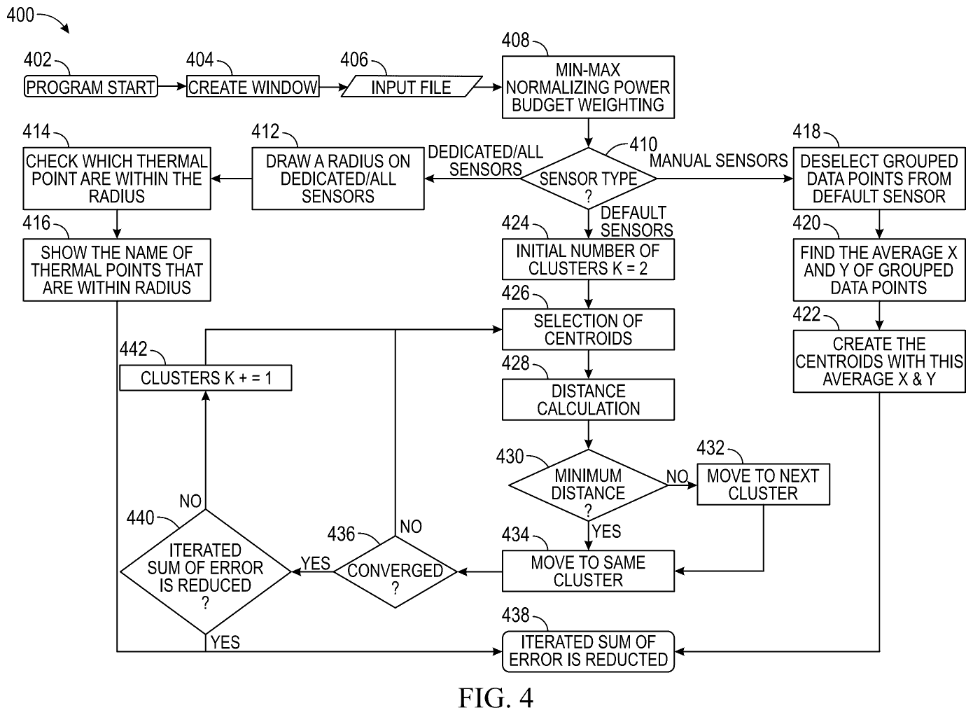

FIG. 4 illustrates another embodiment of a weighted thermal sensor clustering method 400 that may be performed to identify an optimal quantity and placement of clusters 206 representing a collection of heat generating components according to one embodiment of the present disclosure. The method 400 includes steps 402-422 and 426-434 that are at least somewhat similar to steps 302-322 and 326-334 of FIG. 3. The method 400 differs, however, from the method 300 of FIG. 3 in that it includes steps 424 and 436-440 that will be described in detail herein below. That is, whereas the method 300 of FIG. 3 identifies an optimal placement of clusters 206, the method 400 of FIG. 4 identifies an optimal placement of clusters 206 as well as an optimal quantity of clusters 206.

At step 424, the weighted thermal sensor clustering tool 202 initially starts the iterative procedure using a specified initial quantity of clusters 206, which in the present embodiment is two clusters 206. Later on at step 436, the weighted thermal sensor clustering tool 202 uses the selected groupings for the components 216 in each of the clusters 206 to determine whether the placement of the centroids 220 is sufficiently converged. If the centroids 220 are not optimally placed, processing continues at step 426 to again select another placement for the centroids 220 that would reduce the distance of the centroids 220 from the heat generating components 216. If, however, the weighted thermal sensor clustering tool 202 determines that the centroids 220 are optimally placed, processing continues at step 440 in which it determines whether the difference of the sum of error relative to the previous sum of error is less than a specified amount (e.g., 5 percent (%)).

The difference of the sum of error relative to the previous sum of error is less than a specified amount may indicate whether the current quantity of centroids 220 or sensors is sufficient or not. Thus, if the difference of the sum of error relative to the previous sum of error is less than a specified amount, processing continues at step 438 in which the centroids 220 are displayed on the user interface 210 for view by the user, and in which the method 400 ends. If, however, the difference of the sum of error relative to the previous sum of error is not less than a specified amount, processing continues at step 442 in which another cluster 206 is added to the total quantity of clusters 206, and the method 400 continues again at step 426 to select a location for the centroids 220 of the clusters 206.

Thus as can be seen, while the method 300 of FIG. 3 provides only for determining a location of a specified quantity of default sensors, the method 400 provides an advanced optimization approach, which can reduce or increase the number of sensors when the default sensors are either excessive or insufficient.

Although FIGS. 3 and 4 describe example methods 300, 400 that may be performed to identify an optimal placement of clusters 206 representing a collection or grouping of heat generating components, the features of either of the methods 300, 400 may be embodied in other specific forms without deviating from the spirit and scope of the present disclosure. For example, either of the methods 300, 400 may perform additional, fewer, or different operations than those described in the present examples. For another example, either of the methods 300, 400 may be performed in a sequence of steps different from that described above. As yet another example, certain steps of either of the methods 300, 400 may be performed by other components than those described above.

To implement various operations described herein, computer program code (i.e., program instructions for carrying out these operations) may be written in any combination of one or more programming languages, including an object-oriented programming language such as Java, Smalltalk, Python, C++, or the like, conventional procedural programming languages, such as the “C” programming language or similar programming languages, or any of machine learning software. These program instructions may also be stored in a computer readable storage medium that can direct a computer system, other programmable data processing apparatus, controller, or other device to operate in a particular manner, such that the instructions stored in the computer readable medium produce an article of manufacture including instructions which implement the operations specified in the block diagram block or blocks.

Program instructions may also be loaded onto a computer, other programmable data processing apparatus, controller, or other device to cause a series of operations to be performed on the computer, or other programmable apparatus or devices, to produce a computer implemented process such that the instructions upon execution provide processes for implementing the operations specified in the block diagram block or blocks.

Modules implemented in software for execution by various types of processors may, for instance, include one or more physical or logical blocks of computer instructions, which may, for instance, be organized as an object or procedure. Nevertheless, the executables of an identified module need not be physically located together but may include disparate instructions stored in different locations which, when joined logically together, include the module and achieve the stated purpose for the module. Indeed, a module of executable code may be a single instruction, or many instructions, and may even be distributed over several different code segments, among different programs, and across several memory devices.

Similarly, operational data may be identified and illustrated herein within modules and may be embodied in any suitable form and organized within any suitable type of data structure. Operational data may be collected as a single data set or may be distributed over different locations including over different storage devices.

Reference is made herein to “configuring” a device or a device “configured to” perform some operation(s). It should be understood that this may include selecting predefined logic blocks and logically associating them. It may also include programming computer software-based logic of a retrofit control device, wiring discrete hardware components, or a combination thereof. Such configured devices are physically designed to perform the specified operation(s).

It should be understood that various operations described herein may be implemented in software executed by processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs.

As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

1. An Information Handling System (IHS), comprising:
at least one memory coupled to the at least one processor, the at least one memory having program instructions stored thereon that, upon execution by the at least one processor, cause the IHS to:
receive a component location file that indicates the location of a plurality of components on a printed circuit board (PCB);
identify an optimal location of a plurality of heat source clusters on a computing device using the component location file; and
display the heat source clusters along with their location relative to the computing device on a user interface for view by the user.

2. The IHS of claim 1, wherein the program instructions further cause the processor to receive user input for manual selection of at least one of the clusters.

3. The IHS of claim 1, wherein the program instructions further cause the processor to receive user input for manual selection of at least one dedicated cluster.

4. The IHS of claim 1, wherein the component location file comprises an xlsx file.

5. The IHS of claim 1, wherein the program instructions further cause the processor to identify the optimal location using a Machine Learning (ML) algorithm.

6. The IHS of claim 1, wherein the program instructions further cause the processor to identify the optimal location using a K-means classifier.

7. The IHS of claim 1, wherein the program instructions further cause the processor to identify the optimal location using a revised K-means classifier.

8. The IHS of claim 1, wherein the program instructions further cause the processor to apply a weighted value to each of the components based upon their rated energy usage.

9. The IHS of claim 1, wherein the program instructions further cause the processor to identify an optimal quantity of clusters on the computing device using the component location file.

10. A weighted thermal sensor clustering method comprising:
receiving a component location file that indicates the location of a plurality of components on a printed circuit board (PCB);
identifying an optimal location of a plurality of heat source clusters on a computing device using the component location file; and
displaying the heat source clusters along with their location relative to the computing device on a user interface for view by the user.

11. The weighted thermal sensor clustering method of claim 10, further comprising receiving user input for manual selection of at least one of the clusters.

12. The weighted thermal sensor clustering method of claim 10, further comprising receiving user input for manual selection of at least one dedicated cluster.

13. The weighted thermal sensor clustering method of claim 10, further comprising identifying the optimal location using a Machine Learning (ML) algorithm.

14. The weighted thermal sensor clustering method of claim 10, further comprising identifying the optimal location using a K-means classifier.

15. The weighted thermal sensor clustering method of claim 10, further comprising identifying the optimal location using a revised K-means classifier.

16. The weighted thermal sensor clustering method of claim 10, further comprising applying a weighted value to each of the components based upon their rated energy usage.

17. The weighted thermal sensor clustering method of claim 10, further comprising identifying an optimal quantity of clusters on the computing device using the component location file.

18. A non-transitory memory storage device having program instructions stored thereon that, upon execution by one or more processors of a client Information Handling System (IHS), cause the IHS to:
receive a component location file that indicates the location of a plurality of components on a printed circuit board (PCB);
identify an optimal location of a plurality of heat source clusters on a computing device using the component location file; and
display the heat source clusters along with their location relative to the computing device on a user interface for view by the user.

19. The non-transitory memory storage device of claim 18, wherein the program instructions further cause the processor to identify the optimal location using a Machine Learning (ML) algorithm.

20. The non-transitory memory storage device of claim 18, wherein the program instructions further cause the processor to apply a weighted value to each of the components based upon their rated energy usage.
